(19) United States
(12) Patent Application Publication
(10) Pub. No.: US 2019/0206756 A1
(43) Pub. Date: Jul. 4, 2019

(54) SEMICONDUCTOR PACKAGE

(71) Applicant: SAMSUNG ELECTRO-MECHANICS CO., LTD., Suwon-si (KR)

(72) Inventors: Joon Sung KIM, Suwon-Si (KR); Doo Hwan LEE, Suwon-Si (KR); Joo Young CHOI, Suwon-Si (KR); Byung Ho KIM, Suwon-Si (KR); Da Hee KIM, Suwon-Si (KR); Tae Wook KIM, Suwon-Si (KR)

(21) Appl. No.: 16/120,131

(22) Filed: Aug. 31, 2018

(30) Foreign Application Priority Data
Jan. 2, 2018 (KR) 10-2018-0000415

(51) Int. Cl. H01L 23/31; H01L 23/13; H01L 23/00; H01L 23/14; H01L 23/538; H01L 21/683; H01L 21/56; H01L 21/48

(52) U.S. Cl. CPC H01L 23/3128; H01L 24/13; H01L 24/20; H01L 24/05; H01L 23/145; H01L 23/5386; H01L 21/6835; H01L 24/19; H01L 21/568; H01L 23/562; H01L 21/481; H01L 23/5389; H01L 2224/13024; H01L 2224/211; H01L 2924/3511; H01L 2224/05124; H01L 2224/0401; H01L 24/03; H01L 2224/03462; H01L 2224/03464; H01L 2224/02331; H01L 2224/0231; H01L 2224/02379; H01L 23/13

(57) ABSTRACT

A semiconductor package includes a support member having first and second surfaces opposing each other, including a cavity penetrating through the first and second surfaces, and having a primer layer disposed on the first surface; a connection member disposed on the first surface of the support member and having a redistribution layer, the primer layer being disposed between the connection member and the support member; a semiconductor chip having an active surface on which connection pads are disposed and an inactive surface opposing the active surface, the connection pads being electrically connected to the redistribution layer; and an encapsulant covering the second surface of the support member and the inactive surface of the semiconductor chip.

### CROSS-REFERENCE TO RELATED APPLICATION(S)

This application claims benefit of priority to Korean Patent Application No. 10-2018-0000415 filed on Jan. 2, 2018 in the Korean Intellectual Property Office, the disclosure of which is incorporated herein by reference in its entirety.

### TECHNICAL FIELD

The present disclosure relates to a semiconductor package.

### BACKGROUND

Semiconductor packages have continuously been required to be thinned, in terms of a shape and lightened, and have been required to be implemented in a system in package (SiP) form requiring complexation and multifunctionality in terms of a function.

One type of package technology suggested to satisfy the technical demand as described above is a fan-out semiconductor package. In order to mechanically reinforce such a fan-out semiconductor package, a support member may be employed. The semiconductor package may be miniaturized by forming a cavity in the support member and mounting a semiconductor chip in the cavity.

### SUMMARY

An aspect of the present disclosure may provide a semiconductor package for preventing a defect caused by a reinforcing material exposed on a surface of a support member in a process of forming a cavity.

An aspect of the present disclosure may provide a semiconductor package in which a primer layer is applied to a surface of a support member in order to prevent a defect caused by a reinforcing material exposed on the surface of the support member in a process of forming a cavity.

According to an aspect of the present disclosure, a semiconductor package may include a support member having first and second surfaces opposing each other, including a cavity penetrating through the first and second surfaces, and having a primer layer disposed on the first surface; a connection member disposed on the first surface of the support member and having a redistribution layer, the primer layer being disposed between the connection member and the support member; a semiconductor chip having an active surface on which connection pads are disposed and an inactive surface opposing the active surface, the connection pads being electrically connected to the redistribution layer; and an encapsulant covering the second surface of the support member and the inactive surface of the semiconductor chip.

According to another aspect of the present disclosure, a semiconductor package may include a support member having first and second surfaces opposing each other, including a cavity penetrating through the first and second surfaces, and having first and second primer layers disposed on the first surface and the second surface, respectively; a connection member disposed on the first surface of the support member and having an insulating member in direct contact with the first primer layer and a redistribution layer disposed on the insulating member; a semiconductor chip having an active surface on which connection pads are disposed and an inactive surface opposing the active surface, the connection pads being electrically connected to the redistribution layer; and an encapsulant covering the first surface of the support member and the inactive surface of the semiconductor chip. The support member may include a resin in which a reinforcing material is impregnated, and the first and second primer layers may include a resin layer that does not contain the reinforcing material.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is a schematic cross-sectional view illustrating a packaging process of a fan-in semiconductor package;

FIG. 5 is a schematic cross-sectional view illustrating a case in which a fan-in semiconductor package is mounted on an interposer substrate and is finally mounted on a main board of an electronic device;

FIG. 6 is a schematic cross-sectional view illustrating a case in which a fan-in semiconductor package is embedded in an interposer substrate and is finally mounted on a main board of an electronic device;

FIG. 7 is a schematic cross-sectional view illustrating a fan-out semiconductor package;

FIG. 8 is a schematic cross-sectional view illustrating a case in which a fan-out semiconductor package is mounted on a main board of an electronic device;

FIG. 9 is a side cross-sectional view illustrating a semiconductor package according to an exemplary embodiment in the present disclosure;

FIG. 10 is a cross-sectional view of the semiconductor package illustrated in FIG. 9 taken along a line I-I′;

FIGS. 11A through 11F are cross-sectional views for describing main processes of a method of manufacturing the semiconductor package illustrated in FIG. 9;

FIG. 12 is a side cross-sectional view illustrating a semiconductor package according to an exemplary embodiment in the present disclosure; and

FIG. 13 is a cross-sectional view of the semiconductor package illustrated in FIG. 12 taken along a line II-II′.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

Electronic Device

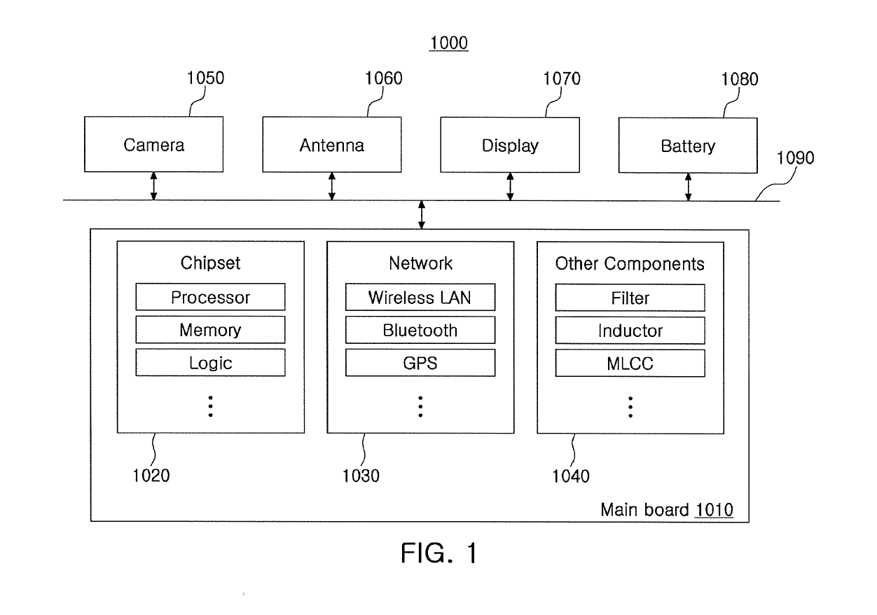

FIG. 1 is a schematic block diagram illustrating an example of an electronic device system.

Referring to FIG. 1, an electronic device 1000 may accommodate a main board 1010 therein. The main board 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter (ADC), an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), and the like. However, other components 1040 are not limited thereto, and may also include passive components used for various other purposes, and the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the main board 1010. These other components may include, for example, a camera 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet personal computer (PC), a laptop PC, a netbook PC, a television, a video game machine, a smartwatch, an automotive, or the like. However, the electronic device 1000 is not limited thereto, but may be any other electronic device processing data.

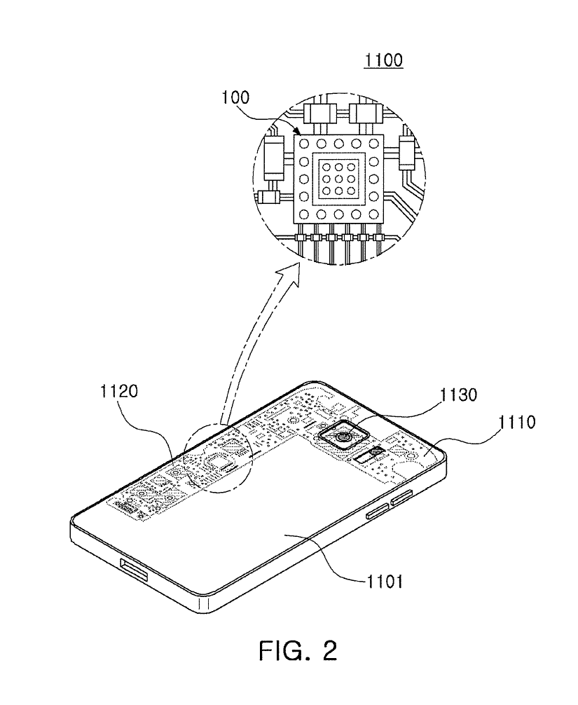

FIG. 2 is a schematic perspective view illustrating an example of an electronic device.

Referring to FIG. 2, a semiconductor package may be used for various purposes in the various electronic devices 1000 as described above. For example, a mother board 1110 may be accommodated in a body 1101 of a smartphone 1100, and various components 1120 may be physically or electrically connected to the mother board 1110. In addition, other components that may or may not be physically or electrically connected to the main board 1010, such as a camera 1130, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a semiconductor finished product in oneself, and may be damaged due to external physical or chemical impact. Therefore, the semiconductor chip is not used in oneself, and is packaged and is used in an electronic device, or the like, in a package state.

The reason why semiconductor packaging is required is that there is a difference in a circuit width between the semiconductor chip and a main board of the electronic device in terms of electrical connection. In detail, a size of connection pads of the semiconductor chip and an interval between the connection pads of the semiconductor chip are very fine, but a size of component mounting pads of the main board used in the electronic device and an interval between the component mounting pads of the main board are significantly larger than those of the semiconductor chip. Therefore, it may be difficult to directly mount the semiconductor chip on the main board, and packaging technology for buffering a difference in a circuit width between the semiconductor and the main board is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-In Semiconductor Package

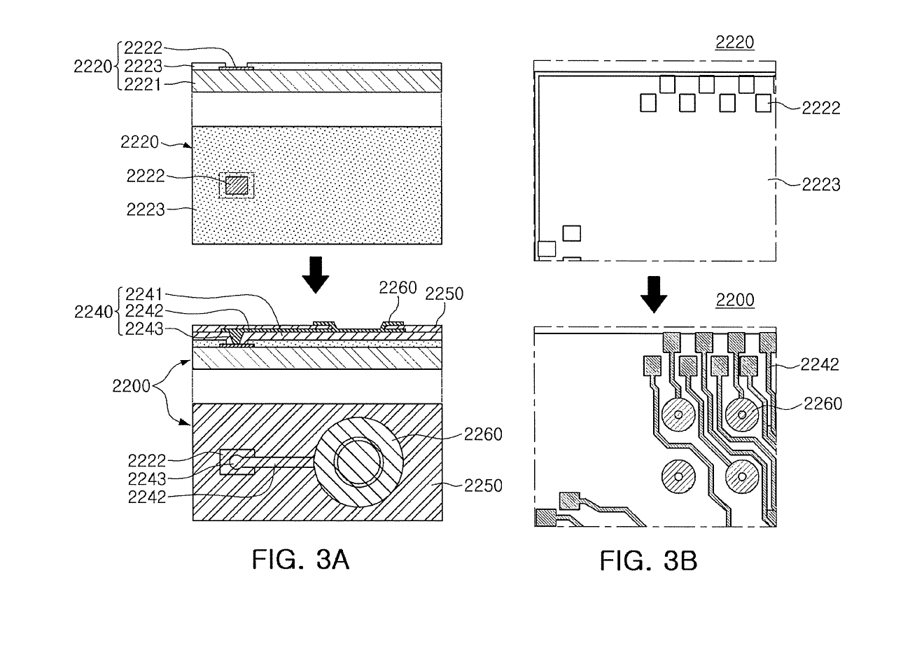

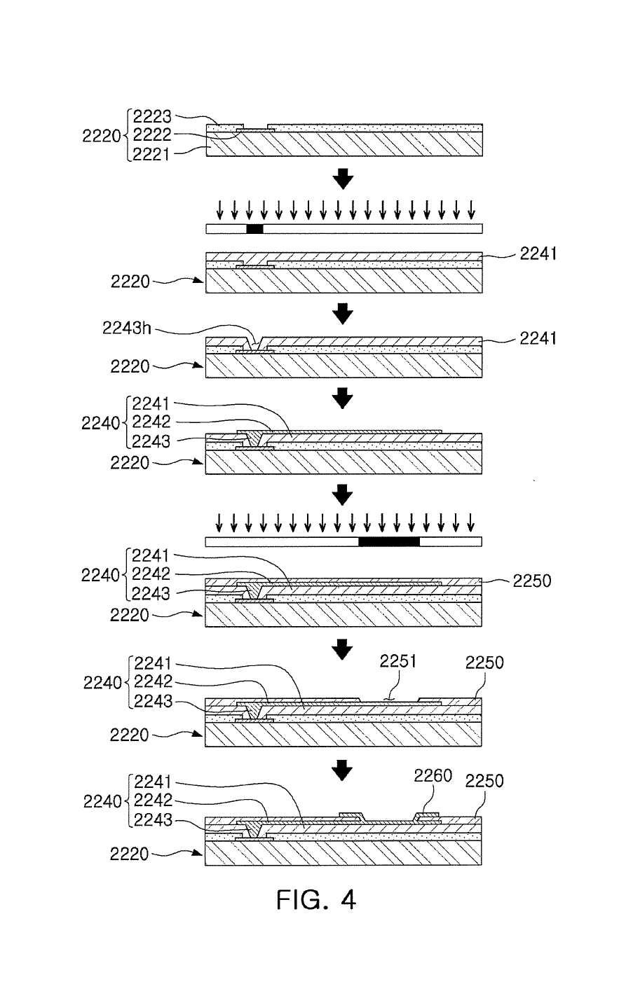

FIGS. 3A and 38 are schematic cross-sectional views illustrating states of a fan-in semiconductor package before and after being packaged, and FIG. 4 is schematic cross-sectional views illustrating a packaging process of a fan-in semiconductor package.

Referring to FIGS. 3A to 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 are significantly small, it is difficult to mount the integrated circuit (IC) on an intermediate level printed circuit board (PCB) as well as on the main board of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has a large spatial limitation. Therefore, it is difficult to apply this structure to a semiconductor chip having a large number of I/O terminals or a semiconductor chip having a small size. In addition, due to the disadvantage described above, the fan-in semiconductor package may not be directly mounted and used on the main board of the electronic device. The reason is that even in the case that a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the main board of the electronic device.

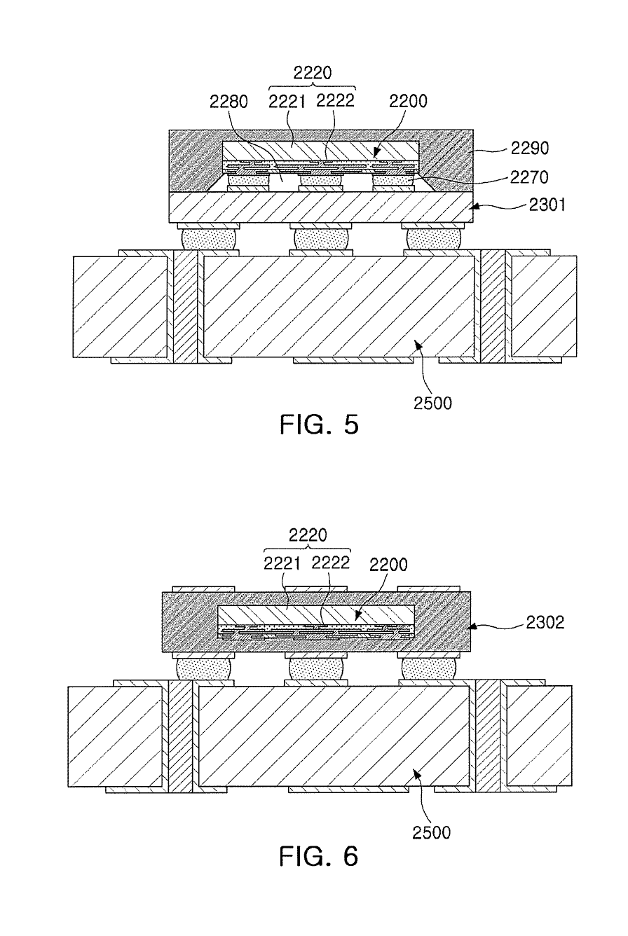

FIG. 5 is a schematic cross-sectional view illustrating a case in which a fan-in semiconductor package is mounted on an interposer substrate and is finally mounted on a main board of an electronic device, and FIG. 6 is a schematic cross-sectional view illustrating a case in which a fan-in semiconductor package is embedded in an interposer substrate and is finally mounted on a main board of an electronic device.

Referring to FIGS. 5 and 6, in a fan-in semiconductor package 2200, connection pads 2222, that is, I/O terminals, of a semiconductor chip 2220 may be redistributed once more through an interposer substrate 2301, and the fan-in semiconductor package 2200 may be finally mounted on a main board 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with an encapsulant 2290, or the like. Alternatively, a fan-in semiconductor package 2200 may be embedded in a separate interposer substrate 2302, connection pads 2222, that is, I/O terminals, of a semiconductor chip 2220 may be redistributed once more by the interposer substrate 2302 in a state in which the fan-in semiconductor package 2200 is embedded in the interposer substrate 2302, and the fan-in semiconductor package 2200 may be finally mounted on a main board 2500 of an electronic device.

As described above, it may be difficult to directly mount and use the fan-in semiconductor package on the main board of the electronic device. Therefore, the fan-in semiconductor package may be mounted on the separate interposer substrate and be then mounted on the main board of the electronic device through a packaging process or may be mounted and used on the main board of the electronic device in a state in which it is embedded in the interposer substrate.

Fan-Out Semiconductor Package

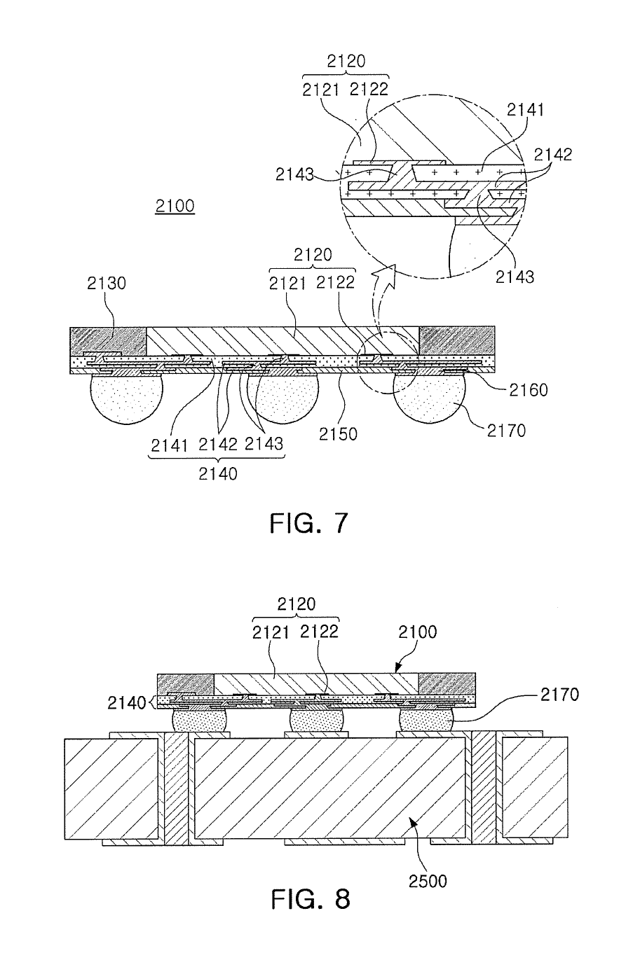

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may be further formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2241, and vias 2143 electrically connecting the connection pads 2122 and the redistribution layers 2142 to each other.

In the present manufacturing process, the connection member 2140 may be formed after the encapsulant 2130 is formed outside the semiconductor chip 2120. In this case, a process for the connection member 2140 is performed from the via connecting the redistribution layers and the connection pads 2122 of the semiconductor chip 2120 to each other and the redistribution layers, and the vias 2143 may thus have a width that becomes small as they become closer to the semiconductor chip (see an enlarged region).

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in the case that a size of the semiconductor chip is decreased, a standardized ball layout may be used in the fan-out semiconductor package as it is, such that the fan-out semiconductor package may be mounted on the main board of the electronic device without using a separate interposer substrate, as described below.

FIG. 8 is a schematic cross-sectional view illustrating a case in which a fan-out semiconductor package is mounted on a main board of an electronic device.

Referring to FIG. 8, a fan-out semiconductor package 2100 maybe mounted on a main board 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the main board 2500 of the electronic device without using a separate interposer substrate, or the like.

As described above, since the fan-out semiconductor package may be mounted on the main board of the electronic device without using the separate interposer substrate, the fan-out semiconductor package maybe implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to occurrence of a warpage phenomenon.

Meanwhile, the fan-out semiconductor package refers to package technology for mounting the semiconductor chip on the main board of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

A semiconductor package capable of preventing a defect caused at the time of mounting electronic components and smoothly supplying a molding material for an encapsulant by machining an inner side wall of a support member will hereinafter be described with reference to the accompanying drawings.

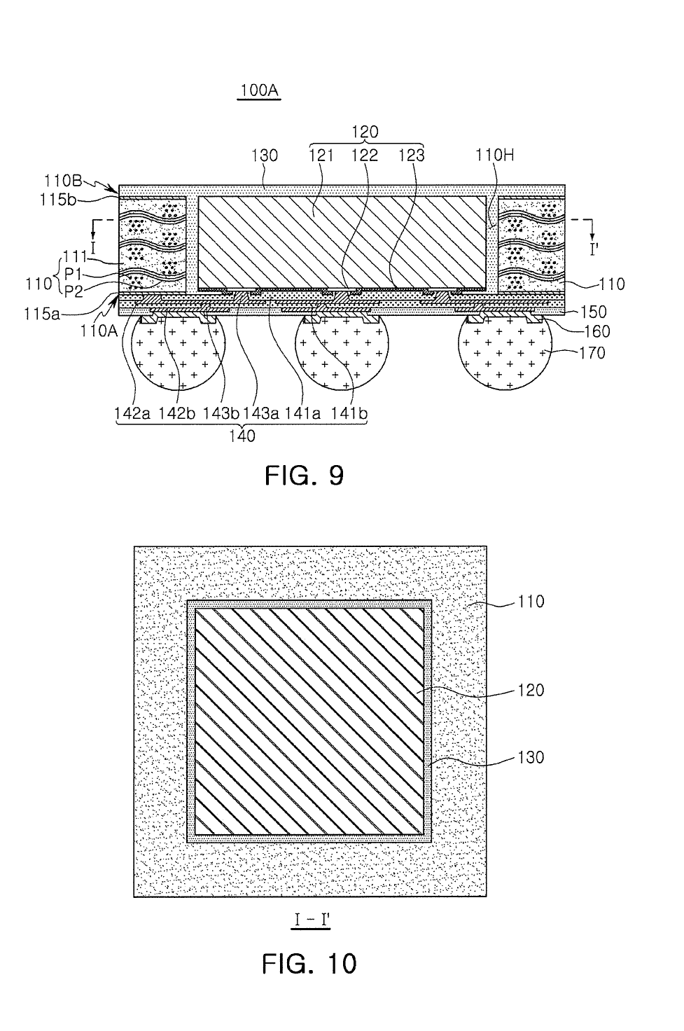

FIG. 9 is a side cross-sectional view illustrating a semiconductor package according to an exemplary embodiment in the present disclosure and FIG. 10 is a cross-sectional view of the semiconductor package illustrated in FIG. 9 taken along a line

Referring to FIG. 9, a semiconductor package 100A according to the present exemplary embodiment may include a support member 110 having first and second surfaces 110A and 110b disposed to oppose each other and having a cavity 110H penetrating through the first and second surfaces 110A and 110B, a connection member 140 including redistribution layers 142a and 142b, a semiconductor chip 120 disposed on the connection member 140 in the cavity 110H, and an encapsulant 130 encapsulating the semiconductor chip 120 disposed in the cavity 110H.

The support member 110 may maintain rigidity of the semiconductor package 100A. The support member 110 may include an insulating resin body 111. For example, the insulating resin body 111 may include a thermosetting resin such as an epoxy resin and a thermoplastic resin such as polyimide, and according to a specific exemplary embodiment, prepreg, ABF (Ajinomoto Build-up Film), FR-4, BT (Bismaleimide Triazine) and the like may be used. A photosensitive insulating material such as a photo imagable dielectric (PID) resin may be used if necessary. The support member 110 employed in the present exemplary embodiment may have reinforcing materials P1 and P2 impregnated in the insulating resin body 111. For example, the reinforcing material may be a glass fiber P1 or an inorganic filler P2.

The support member 110 may include the cavity 110H for mounting the semiconductor chip 120. However, the reinforcing material such as the glass fiber P1 and the filler P2 may be exposed on a surface of the insulating resin body 111 configuring the support member 110 in a desmear process after forming the cavity 110H. This surface state may cause a defect in a process of forming the connection member 140. In detail, when an insulating layer 141a of the connection member 140 is formed on the surface of the support member 110, a void may occur on a portion in which the reinforcement is exposed or adhesion between the surface of the support member 110 and the insulating layer 141a may be significantly reduced.

In order to prevent the above-mentioned problem, first and second primer layers 115a and 115b may be formed on the first and second surfaces 110A and 110B of the support member 110 employed in the present exemplary embodiment. The support member 110 is the resin body 111 in which the reinforcing materials P1 and P2 are impregnated while the primer layers 115a and 115b may include a resin layer that does not contain the above-mentioned reinforcing materials P1 and P2. An exposure of the reinforcing materials P1 and P2 from the insulating resin body 111 in the desmear process after the cavity is formed may be prevented by using the first and second primer layers 115a and 115b.

The first primer layer 115a may secure adhesion between the first surface 110A of the support member 110 and the first insulating layer 141a of the connection member 110. In particular, when a photosensitive insulating material (e.g., PID) for the first insulating layer 141a is applied to the first surface 110A of the connection member 110, the first primer layer 115a may effectively suppress an occurrence of voids due to the exposure of the reinforcing material. Meanwhile, when the encapsulant 130 is applied, the second primer layer 115b may also increase adhesion between the second surface 110B of the support member 110 and the encapsulant 130 to increase bonding strength between two members.

According to some exemplary embodiments, the primer layers 115a and 115b may be formed of an epoxy resin or a primer including iso propyl alcohol and acryl based silan. In a specific example, the primer layers 115a and 115b may be formed of MPS (3-(trimethoxysilyl)propylmethacrylate, and a silan based additive may be added thereto.

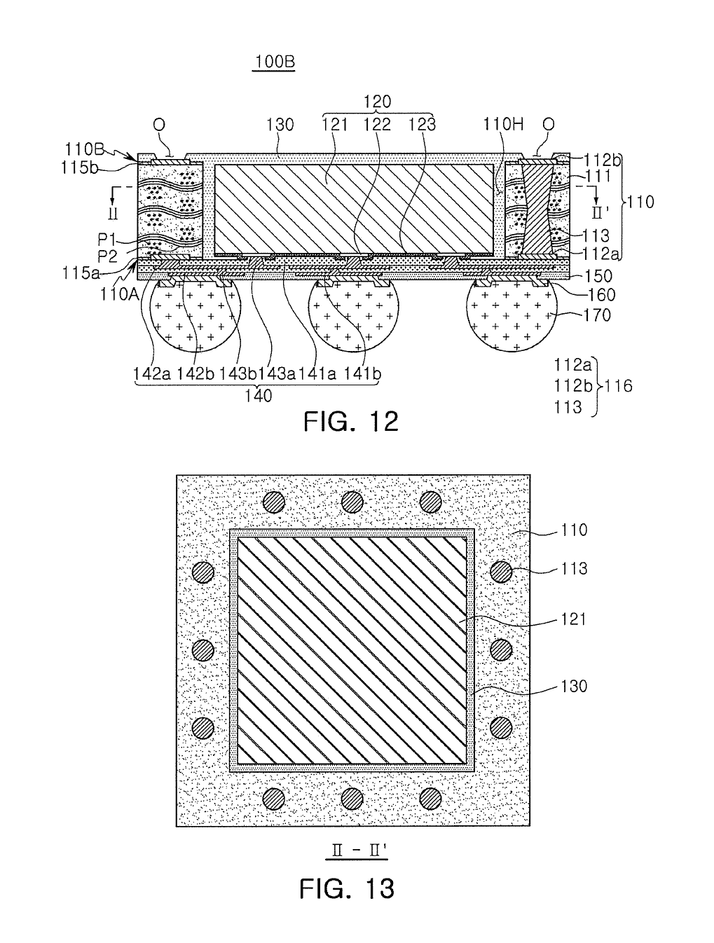

Unlike the present exemplary embodiment, the support member 110 may provide an extended routing region to the semiconductor package 100A and improve a degree of freedom of design. For example, the support member 110 may have a specific wiring structure (see FIGS. 12 and 13).

The present exemplary embodiment illustrates a form in which the first and second primer layers 115a and 115b are applied to the first and second surfaces 110A and 110B of the support member 110, respectively, but according to another exemplary embodiment, only the first primer layer 115a may be provided to only a surface on which the connection member 110 having first and second redistribution layers 142a and 142b are formed, that is, the first surface 110A of the support member 110.

The connection member 140 is a component for redistributing the connection pads 122 of the semiconductor chip 120. Several tens to several hundreds of connection pads 122 having various functions may be redistributed by the connection member 140, and may be physically and/or electrically connected to an external apparatus through external connection terminals 170. The connection member 140 may be connected to the connection pads 122 of the semiconductor chip 120, and support the semiconductor chip 120.

Specifically, the semiconductor chip 120 employed in the present exemplary embodiment may be an integrated circuit (IC). The IC may be, for example, an application processor chip such as a central processor (for example, a CPU), a graphics processor (for example, a GPU), a digital signal processor, a cryptographic processor, a microprocessor, a microcontroller, or the like, but is not limited thereto. The semiconductor chip 120 may be formed based on an active wafer, and in this case, the semiconductor chip 120 may include a body 121 formed of a semiconductor such as silicon (Si), germanium (Ge), and gallium-arsenic (GaAs), and the body 121 may include various circuits. The connection pads 122 may electrically connect the semiconductor chip 120 to other components. A material of each of the connection pads 122 may be a conductive material such as aluminum (Al), or the like. An element passivation layer 123 exposing the connection pads 122 may be formed on a surface of the body 121, and may be an oxide film, a nitride film, or the like, or a double layer of an oxide film and a nitride film. A lower surface of the connection pad 122 may have a step with respect to a lower surface of the encapsulant 130 through the element passivation layer 123. Resultantly, a phenomenon in which the encapsulant 130 bleeds into the lower surface of the connection pads 122 may be prevented to some extent. An insulating layer (not illustrated), and the like, may also be further disposed in other required positions.

The connection member 140 employed in the present exemplary embodiment may have a two-layer redistribution structure including the first and second redistribution layers 142a and 142b disposed on the first and second insulating layers 141a and 142b, respectively. The redistribution structure employable in the present exemplary embodiment is not limited thereto, but may include a single layer or layers more than two layers. The first redistribution layer 142a and the connection pads 122 of the semiconductor chip 120 may be connected to each other through a first via 143a formed in the first insulating layer 141a. Similarly, the second redistribution layer 142b may be connected to the first redistribution layer 142a through a second via 143b formed in the second insulating layer 141b.

Similarly to the insulating resin body 111 described above, the first and second insulating layers 141a and 141b may include a thermosetting resin such as an epoxy resin and a thermoplastic resin such as polyimide. The first and second insulating layers 141a and 141b may use a photosensitive insulating material such as PID. According to the present exemplary embodiment, as described above, since a surface treatment is performed by the first primer layer 115a when the first insulating layer 141a is applied to the first surface 110A of the support member 110, the defect (e.g., an occurrence of voids) caused by the reinforcing material (e.g., a glass fiber P1) exposed at the time of desmear process may be prevented. The redistribution structure, that is, the first and second redistribution layers 142a and 142b, and the first and second vias 143a and 143b of the connection member 140 may include, for example, a conductive material such as copper (Cu), aluminum (Al), silver (Ag), tin (Sn), gold (Au), nickel (Ni), lead (Pb), or alloys of thereof.

Meanwhile, the semiconductor package 100A according to the exemplary embodiment may further include the passivation layer 150 disposed below the connection member 140. The passivation layer 150 may be a component for protecting the connection member 140 from external physical or chemical damage.

The passivation layer 150 employed in the present exemplary embodiment may be formed on the second redistribution layer 142b so that some regions of the second redistribution layer 142b are exposed. An under bump metallurgy 160 connected to some regions of the second redistribution layer 142b may be disposed on the passivation layer 150.

A material of the passivation layer 150 is not particularly limited. For example, a solder resist may be used as the material of the passivation layer 150. In some exemplary embodiments, a material (for example, a PID resin, ABF, or the like) that is the same as or similar to the insulating material used as the material of the support member 110 and/or the connection member 140 may be used as the material of the passivation layer 150.

According to the present exemplary embodiment, the under bump metallurgy 160 may be additionally formed on the second redistribution layer 142b and the external connection terminal 170 may be formed on the under bump metallurgy 160. The external connection terminals 170 may be a component for physically and/or electrically connecting the semiconductor package 100A to the outside. For example, the semiconductor package 100A may be mounted on a mother board of the electronic device through the external connection terminal 170. For example, the external connection terminal 170 may be formed of a low melting point eutectic metal such as copper (Cu), aluminum (Al), silver (Ag), tin (Sn), gold (Au), nickel (Ni), or an alloy of Sn—Al—Cu, but is not limited thereto. In addition, external connection terminals 170 may be various structures such as lands, balls, pins, or the like.

The encapsulant 130 may be a component for protecting the semiconductor chip 120. According to the present exemplary embodiment, an encapsulation form of the encapsulant 130 is not particularly limited, but may be a form in which the encapsulant 130 surrounds the semiconductor chip 120. For example, the encapsulant 130 may cover the semiconductor chip 120, and may fill the remaining space within the cavity 110H of the support member 110. The encapsulant 130 may fill the cavity 110H to thus serve as an adhesive and reduce buckling of the semiconductor chip 120. The encapsulant 130 may cover all surfaces of the semiconductor chip 120 except for a lower surface of the semiconductor chip 120. The encapsulant 140 may cover only portions of the lower surface of the semiconductor chip 120 depending on positions and shapes of the connection pads 122 of the semiconductor chip 120.

According to some exemplary embodiments, the encapsulant 130 may be formed in a plurality of layers and the plurality of layers may be formed of different materials. For example, a space in the cavity 110H may be filled with a first encapsulant, and the second surface 110B of the support member 110 and an upper surface (i.e., an inactive surface) of the semiconductor chip 120 may be covered with a second encapsulant different from the first encapsulant. A material of the encapsulant 130 is not particularly limited, but may be thermosetting resin such as an epoxy resin, a thermoplastic resin such as a polyimide resin, a resin in which a thermosetting resin or a thermoplastic resin is impregnated in a reinforcing material such as a glass fiber and/or an inorganic filler, for example, prepreg, ABF, or the like. In addition, the known molding material such as an epoxy molding compound (EMC), or the like, may be used. In some exemplary embodiments, a material including a glass fiber and/or an organic and/or inorganic filler and an insulating resin may be used as a material of the encapsulant 130 to effectively suppress warpage of the semiconductor package. In addition, the encapsulant 130 may also include conductive particles in order to block an electromagnetic wave. For example, the conductive particles may include copper (Cu), aluminum (Al), silver (Ag), tin (Sn), gold (Au), or nickel (Ni), but are not limited thereto.

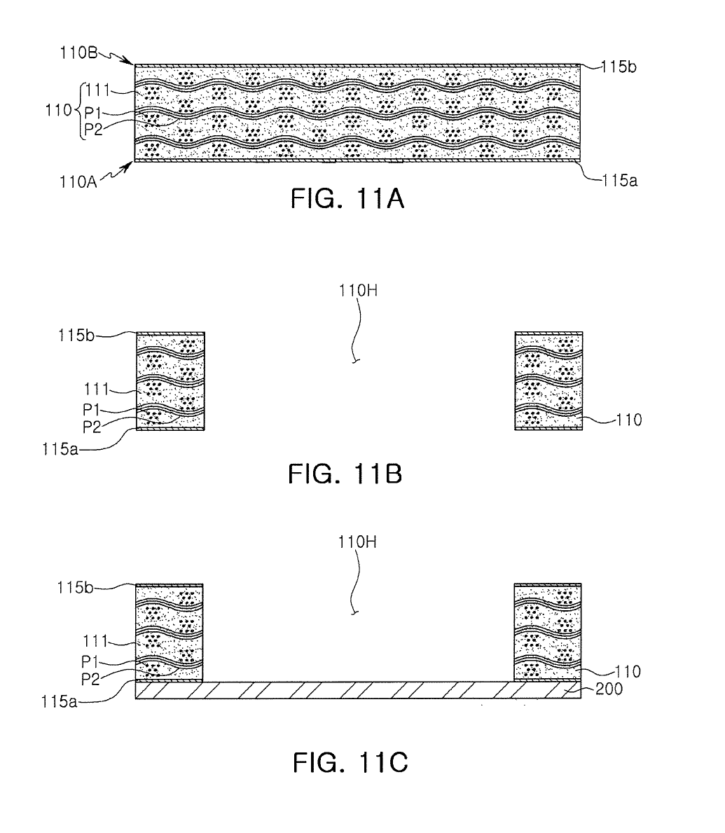

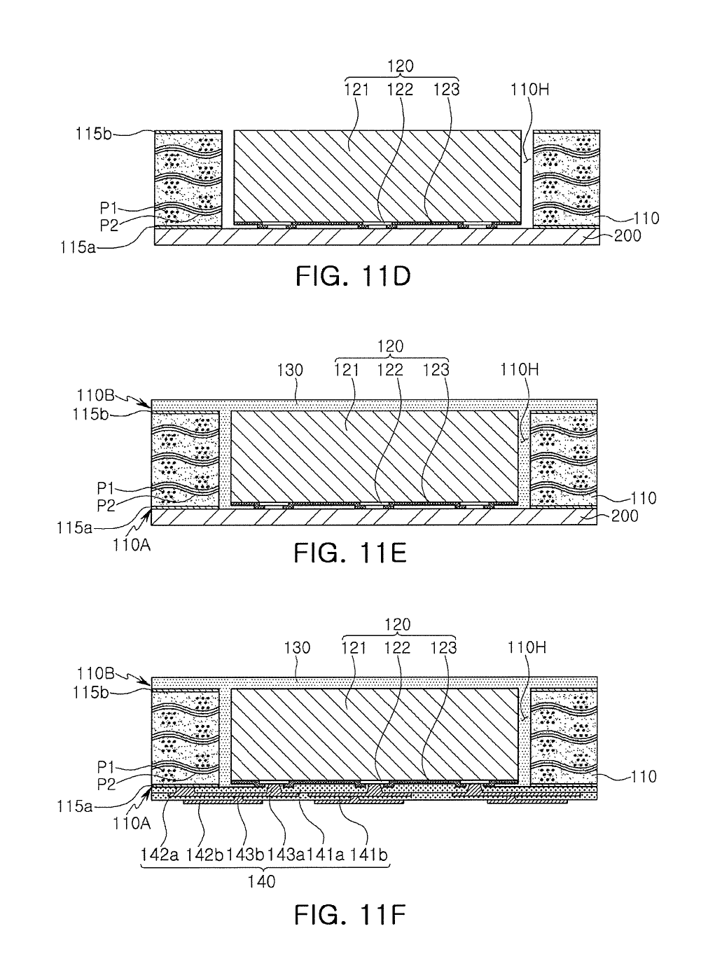

FIGS. 11A through 11F are cross-sectional views for describing main processes of a method of manufacturing the semiconductor package illustrated in FIG. 9.

Referring to FIG. 11A, the support member 110 having the first and second surfaces 110A and 110B disposed to oppose each other may be prepared and the first and second primer layer may be formed on the first and second surfaces of the support member 110, respectively.

The support member 110 may include an insulating structure 111. The insulating structure ill may include a thermosetting resin such as an epoxy resin and a thermoplastic resin such as polyimide, and may further include various forms of reinforcing materials such as a glass fiber P1 and/or an organic or inorganic filler P2. For example, the insulating structure 111 may include prepreg, ABF, FR-4 or BT. Since the prepreg including the reinforcing material such as the glass fiber has high rigidity, the prepreg may be advantageously used as the support member 110 for controlling warpage of the semiconductor package 100A.

The first and second primer layers 115a and 115b may be formed on the first and second surfaces 110A and 110B of the support member 110 employed in the present exemplary embodiment. The primer layers 115a and 115b may be formed of a rein layer that does not contain the above-mentioned reinforcing materials P1 and P2. For example, the primer layers 115a and 115b may be formed of an epoxy resin or a primer including iso propyl alcohol and acryl based silan. In a specific example, the primer layers 115a and 115b may be formed of MPS (3-(trimethoxysilyl)propylmethacrylate, and a silan based additive may be added thereto.

Next, referring to FIG. 11B, the cavity 110H for mounting the semiconductor chip may be formed in the support member 110.

The cavity 110H may be formed using a mechanical drilling or laser drilling. However, the cavity 110H is not limited thereto, and may also be formed by a sand blasting method using particles for polishing, a dry etching method using plasma, or the like. In a case in which the cavity 110H is formed using mechanical drilling or laser drilling, a desmear process such as a permanganate method, or the like, may be performed to remove resin smear from a surface of the cavity 110H.

The above-mentioned desmear process may affect the surface of the insulating resin body 111 constituting the support member 110 and cause an undesired exposure of the reinforcing materials such as the glass fiber P1 and the filler P2 on the surface of the insulating resin body 111. The surface of the insulating resin body 111 described above may cause a reduction in adhesion with another component (e.g., the connection member or the encapsulant) and/or a defect of occurrence of voids.

The first and second primer layers 115a and 115b employed in the present exemplary embodiment may protect the surface of the insulating resin body 111 in the desmear process to suppress the problem such as the undesired exposure of the reinforcing materials P1 and P2, and may secure sufficient adhesion strength with another component (e.g., the connection member or the encapsulant) provided to the surface of the support member 110.

Next, referring to FIG. 11C, a carrier film 200 may be attached to the first surface 110A of the support member 110.

The carrier film 200 maybe disposed on the first surface 110A of the support member 110 and may be used as a supporter for treating the support member 110 in a subsequent process such as a process of forming a cavity. The carrier film 200 may be various known types of adhesive films. For example, the adhesive film may be a thermosetting adhesive tape of which adhesion is weakened by heat treatment, an ultraviolet-curable adhesive tape of which adhesion is weakened by ultraviolet ray irradiation, or the like. As another example, the carrier film 200 employed in the present exemplary embodiment may be a copper foil laminate such as DCF, including an insulating layer and a metal layer.

Next, referring to FIG. 11D, the semiconductor chip 120 may be disposed in the cavity 110H of the support member 110.

The semiconductor chip 120 on the carrier film 200 in the cavity 110H may be disposed in a face-down form so that the connection pads 122 are attached to the carrier film 200. One surface of the connection pad 122 may be attached so as to have a step with respect to an upper surface of the carrier film 200. For example, the connection pads 122 may be attached so as to be recessed in an inner side direction of the carrier film 200 even after being attached to the carrier film 200.

Next, referring to FIG. 11E, the semiconductor chip 120 disposed in the cavity 110H may be encapsulated by using the encapsulant 130.

The encapsulant 130 may be formed by a known method and may encapsulate the semiconductor chip 120 disposed on the carrier film 200. For example, the encapsulant 130 may also be formed by applying a liquid resin or laminating the film and then curing the laminated film. The semiconductor chip 120 may be fixed to the support member 110 through the curing process described above. As a method of applying a resin, for example, various processes such as a screen printing method of applying ink with a squeegee, a spray printing method of applying ink in a mist form, and the like, may be used. As described above, when the lamination method is used, a method of performing a hot press process of pressing the film for a predetermined time at a high temperature, decompressing the film, and then cooling the film to room temperature, and separating a work tool by cooling the film in a cold press process, or the like, may be used.

The encapsulant 130 formed in the present process may be disposed to cover the second surface 110B of the support member 110. In this case, since the second surface 110B of the support member 110 maintains a good surface state even in the preceding desmear process by the previously formed second primer layer 115b, the second surface 110B of the support member 110 may be bonded to the encapsulant 130 with high adhesion.

Next, referring to FIG. 11F, the carrier film 200 may be removed, and the connection member 140 maybe formed on the active surface (the surface on which the connection pads 122 are disposed) of the semiconductor chip 120 and the first surface 110A of the support member.

A method of removing the carrier film 200 is not particularly limited, and the carrier film 200 may be removed by the known methods (e.g., physical peel-off, heat treatment, ultraviolet irradiation, and the like). The connection member 140 may be obtained by sequentially forming the first and second insulating layers 141a and 141b, and forming the first and second redistribution layers 142a and 142b and the first and second vias 143a and 143b in the first and second insulating layers 141a and 141b, respectively. In particular, in the present process of forming the redistribution layer, since the first primer layer 115a may secure adhesion between the first surface 110A of the support member 110 and the first insulating layer 141a of the connection member 140, the primer layer 115a may effectively suppress an occurrence of voids due to the exposure of the reinforcing material when the photosensitive insulating material (e.g., PID) for the first insulating layer 141a is applied to the first surface 110A of the support member 110. As a result, the connection member 140 may also be formed on the first surface 110A of the support member with high adhesion strength.

Additionally, as illustrated in FIG. 9, the passivation layer 150 may be formed on the connection member 140. In addition, the semiconductor package 100A illustrated in FIG. 9 may be manufactured by exposing a portion of the second redistribution layer 142b and then forming an external connection terminal 170. The under bump metallurgy layer 160 maybe formed before forming the external connection terminal 170, if necessary.

FIG. 12 is a side cross-sectional view illustrating a semiconductor package according to an exemplary embodiment in the present disclosure and FIG. 13 is a cross-sectional view of the semiconductor package illustrated in FIG. 12 taken along a line

Referring to FIGS. 12 and 13, a semiconductor package 100B according to the present exemplary embodiment may be understood to be similar to the structure illustrated in FIGS. 9 and 10, except that the support member 110 having a wiring structure 116 is employed and formation regions of the primer layers 115a and 115b are changed. Components according to the present exemplary embodiment maybe understood with reference to the description for the same or similar components of the semiconductor package 100A illustrated in FIGS. 9 and 10 unless explicitly described to the contrary.

Similarly to the exemplary embodiment described above, the support member 110 may maintain rigidity of the semiconductor package 100B, and serve to secure uniformity of a thickness of the encapsulant 130.

In addition, the support member 110 employed in the present exemplary embodiment may have a wiring structure 116 including first and second wiring patterns 112a and 112b disposed on first and second surfaces 110A and 110B of the support member 110, and a through via 113 connecting the first and second wiring patterns 112a and 112b to each other. Therefore, the wiring structure 116 described above may simplify the redistribution structure of the connection member 140, and may reduce, for example, the number of redistribution layers. In the present exemplary embodiment, the support member 110 may also provide pad regions to the second surface 110B of the support member 110 so that the semiconductor package 100B may be used as a portion of package on package (POP).

Specifically, the encapsulant 130 disposed on the second surface 110B of the support member 110 may form openings O so that some regions of the second wiring pattern 112b are exposed and further form bonding pads (not shown), if necessary, to thereby provide regions on which another package or semiconductor chip is mounted. For example the bonding pad may be formed by a plating process such as electrolytic plating or electroless plating.

The first and second primer layers 115a and 115b may be formed on the first and second surfaces 110A and 110B of the support member 110 employed in the present exemplary embodiment. The primer layers 115a and 115b may include a rein layer that does not contain the reinforcing materials P1 and P2. The first and second primer layers 115a and 115b may suppress the reinforcing materials P1 and P2 from being exposed from the insulating resin body 111 in the desmear process.

The first and second primer layers employed in the present exemplary embodiment may be formed in regions in which the first and second wiring patterns 112a and 112b are not formed, on the first and second surfaces 110A and 110B of the support member 110. The present exemplary embodiment illustrates a form in which the first and second primer layers 115a and 115b are applied to the first and second surfaces 110A and 110B of the support member 110, respectively, but only the first primer layer 115a may be provided to only the first surface 110A of the support member 110.

Herein, a lower side, a lower portion, a lower surface, and the like, are used to refer to a direction toward a mounted surface of the fan-out semiconductor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” means the concept including a physical connection and a physical disconnection.

In addition, an ordinal number such as “first” or “second” is used to distinguish one component from another component and does not limit an order and/or importance of the corresponding components. In some cases, a first component may be named a second component and a second component may also be similarly named a first component, without departing from the scope of the present disclosure.

The term “an exemplary embodiment” used herein does not refer to the same exemplary embodiment, and is provided to emphasize a particular feature or characteristic different from that of another exemplary embodiment. However, it is not excluded that the exemplary embodiments described above are implemented in combination with features of other exemplary embodiments. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. For example, singular forms are intended to include plural forms unless the context clearly indicates otherwise.

As set forth above, according to an exemplary embodiment in the present disclosure, in order to prevent the defect caused by a reinforcing material (e.g., a glass fiber or the like) exposed on a surface of the support member in the process of forming the cavity, the semiconductor package in which a primer layer is applied to the surface of the support member may be provided. When an insulating layer for a connection member is formed, an occurrence of voids on the surface of the support member may be prevented. In addition, adhesion between the surface of the support member and an encapsulant may be improved.

While exemplary embodiments have been shown and described above, it will be apparent to those skilled in the art that modifications and variations could be made without departing from the scope of the present invention as defined by the appended claims.

What is claimed is:

1. A semiconductor package comprising:
a support member having first and second surfaces opposing each other, including a cavity penetrating through the first and second surfaces, and having a first primer layer disposed on the first surface;
a connection member disposed on the first surface of the support member and having a redistribution layer, the first primer layer being disposed between the connection member and the support member;
a semiconductor chip having an active surface on which connection pads are disposed and an inactive surface opposing the active surface, the connection pads being electrically connected to the redistribution layer; and
an encapsulant covering the second surface of the support member and the inactive surface of the semiconductor chip.

2. The semiconductor package of claim 1, wherein the first primer layer is not formed on an inner side wall of the cavity.

3. The semiconductor package of claim 1, further comprising a second primer layer disposed on the second surface of the support member.

4. The semiconductor package of claim 1, wherein the support member includes a resin in which a reinforcing material is impregnated.

5. The semiconductor package of claim 4, wherein the reinforcing material includes at least one of a glass fiber, an organic filler, and an inorganic filler.

6. The semiconductor package of claim 4, wherein the first primer layer includes a resin layer that does not contain the reinforcing material.

7. The semiconductor package of claim 6, wherein the resin layer of the first primer layer is at least one of an epoxy resin and an acrylic resin.

8. The semiconductor package of claim 1, wherein the connection member includes an insulator formed of a photosensitive insulating resin.

9. The semiconductor package of claim 1, wherein an insulator of the connection member is in direct contact with the first primer layer.

10. The semiconductor package of claim 1, wherein the support member includes a wiring structure that connects an upper surface and a lower surface of the support member to each other.

11. The semiconductor package of claim 10, wherein the first primer layer is formed on a portion of the first surface of the support member, on which the wiring structure is not formed.

12. A semiconductor package comprising:
a support member having first and second surfaces opposing each other, including a cavity penetrating through the first and second surfaces, and having first and second primer layers disposed on the first surface and the second surface, respectively;
a connection member disposed on the first surface of the support member and having an insulating member in direct contact with the first primer layer and a redistribution layer disposed on the insulating member;
a semiconductor chip having an active surface on which connection pads are disposed and an inactive surface opposing the active surface, the connection pads being electrically connected to the redistribution layer; and
an encapsulant covering the first surface of the support member and the inactive surface of the semiconductor chip,
wherein the support member includes a resin in which a reinforcing material is impregnated, and
the first and second primer layers include a resin layer that does not contain the reinforcing material.
